(19) United States
(12) Patent Application Publication
(10) Pub. No.: US 2026/0314281 A1
(43) Pub. Date: Oct. 8, 2026

(54) CRYSTALLINE DEFECT REDUCTION IN DOPED REGION

(71) Applicant: TEXAS INSTRUMENTS INCORPORATED, Dallas, TX (US)

(72) Inventors: Christopher Thompson, Salt Lake City, UT (US); Jonathan Lane, Sandy, UT (US); Jun Li, Saratoga Springs, UT (US)

(21) Appl. No.: 19/173,742

(22) Filed: Apr. 8, 2025

(51) Int. Cl. H10P 30/22; H10W 10/00; H10W 10/17; H10D 10/01; H10D 10/40

(52) U.S. Cl. CPC H10P 30/22; H10W 10/014; H10W 10/17; H10D 10/051; H10D 10/40

(57) ABSTRACT

The present disclosure generally relates to semiconductor processing for crystalline defects reduction in a doped region. In an example, an isolation structure is formed in a semiconductor substrate. The isolation structure extends from an upper surface of the semiconductor substrate into the semiconductor substrate. The isolation structure laterally surrounds at least in part an area of a bipolar junction transistor (BJT) in the semiconductor substrate. A dopant is implanted in a first region of the area. A second region of the area proximate a sidewall of the isolation structure is covered with a material blocking the dopant. A collector layer is formed on the area.

### BACKGROUND

Integrated circuits may include bipolar junction transistors (BJTs). BJTs may be desirable for their high gain characteristics to satisfy high performance and high current drive needs. Scaling of devices in an integrated circuit to smaller nodes typically requires novel approaches to semiconductor processing for fabricating those devices.

### SUMMARY

An example described herein is a method. An isolation structure is formed in a semiconductor substrate. The isolation structure extends from an upper surface of the semiconductor substrate into the semiconductor substrate. The isolation structure laterally surrounds at least in part an area of a bipolar junction transistor (BJT) in the semiconductor substrate. A dopant is implanted in a first region of the area. A second region of the area proximate a sidewall of the isolation structure is covered with a material blocking the dopant. A collector layer is formed on the area.

Another example is a method. An isolation structure is formed in a semiconductor substrate. The isolation structure extends from an upper surface of the semiconductor substrate into the semiconductor substrate. The isolation structure laterally surrounds at least in part an area of a bipolar junction transistor (BJT) in the semiconductor substrate. A mask is formed over the semiconductor substrate. The mask has an opening exposing a portion of the area. The mask extends laterally from over the isolation structure to a mask sidewall of the opening over the area. A first dopant is implanted, through the opening, in the portion of the area. A collector layer is formed on the area.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIGS. 1 through 7 are respective cross-sectional views of a semiconductor device in intermediate stages of manufacturing according to some examples.

FIG. 8 is a cross-sectional view of a semiconductor device according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to semiconductor processing for reducing crystalline defects, such as stacking faults and/or twin defects, in a doped region. More particularly, examples described herein provide for crystalline defect reduction in a sub-collector region of a bipolar junction transistor (BJT). An isolation structure is formed in a semiconductor substrate. The isolation structure laterally surrounds at least in part an area of a BJT in the semiconductor substrate. A dopant is implanted in a first region of the area, while a second region of the area proximate a sidewall of the isolation structure is covered with a material blocking the dopant. The implantation may amorphize the first region. The first region may be recrystallized, such as by an anneal process, which may use the second region as a crystal seed for recrystallization. Using the second region as a crystal seed may reduce or prevent stacking faults and/or twin defects from forming during recrystallization of the first region. A collector layer may then be formed on the area.

Generally, implanting a dopant into a semiconductor substrate can amorphize the portion of the semiconductor substrate into which the dopant is implanted. Subsequently, an anneal may be performed to activate the dopants and recrystallize the amorphized portion of the semiconductor substrate. If the amorphized portion adjoins another amorphous surface, such as a surface of an oxide, crystalline defects, such as stacking faults and/or twin defects, in the semiconductor substrate at the interface between the semiconductor substrate (e.g., the amorphized portion that is being recrystallized by the anneal) and the other amorphous surface (that is not capable of being crystallized) may be generated during the anneal. Stress between the amorphous surface and the semiconductor substrate may influence the generation of the crystalline defects at the interface. The crystalline defects may propagate through the portion of the semiconductor substrate that is recrystallized by the anneal. This may cause the crystalline defects to be at a surface of the semiconductor substrate where another layer is to be epitaxially grown. Epitaxial growth of a layer on a surface having crystalline defects can cause the crystalline defects to continue to propagate into and through the epitaxially grown layer. These crystalline defects in the semiconductor substrate and in any epitaxially grown layers can form a leakage path for electrons, which may have detrimental effects on the semiconductor device that is formed.

Examples described herein may reduce or avoid crystalline defect generation, such as generation of stacking faults and/or twin defects, by avoiding amorphization of a region that adjoins an amorphized region to be recrystallized. As indicated above, a second region adjoining a first region, where the first region is amorphized by a dopant, may be used as a crystal seed for the recrystallization of the first region. By performing such processing, an amorphous surface (e.g., of an isolation structure) does not interface with the amorphized first region during the anneal, which may reduce or avoid generation of crystalline defects in the doped region. Rather, a crystalline seed from the semiconductor substrate is increased for the recrystallization. By reducing or avoiding such crystalline defects, electrical operation of the semiconductor device may be improved, such as by reducing or avoiding leakage that may otherwise occur due to crystalline defects. Further, examples described herein may provide a robust solution that permits a wide range of implant species, implant energy, and thermally controlled diffusion as may be needed for a target application. Also, examples described herein may also be easily integrated into processing flows including other technologies, such as complementary metal-oxide-semiconductor (CMOS), static random access memory (SRAM), etc. Other benefits and advantages may be achieved.

Various examples are described subsequently. Although the specific examples may illustrate various aspects of the above generally described features, examples may incorporate any combination of the above generally described features (which are described in more detail in examples below).

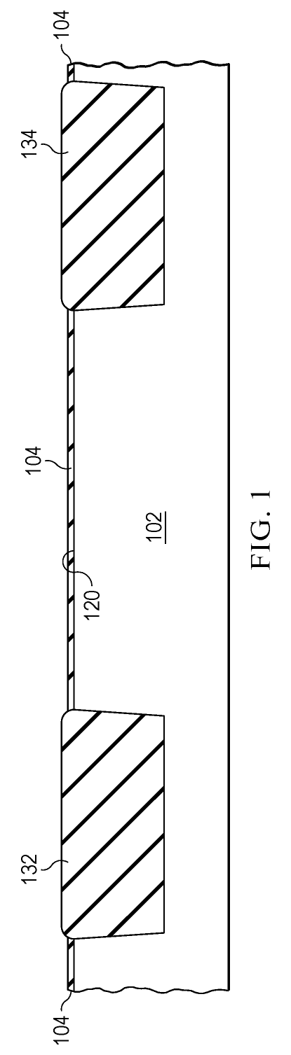

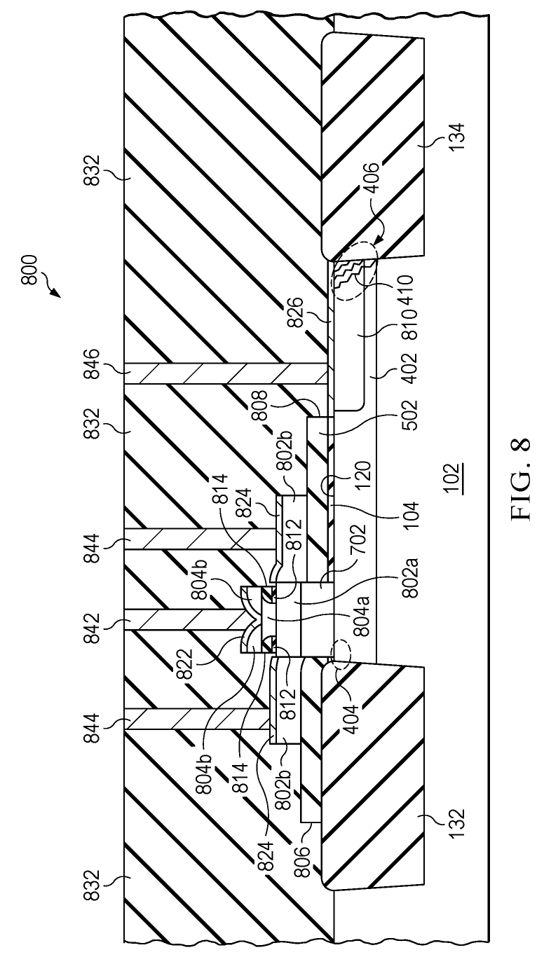

FIGS. 1 through 7 are respective cross-sectional views of a semiconductor device in intermediate stages of manufacturing according to some examples. The method illustrated in these figures may be implemented to form the semiconductor device 800 (e.g., a BJT) of FIG. 8.

Referring to FIG. 1, a first pedestal dielectric sub-layer 104 is formed over a semiconductor substrate 102. The semiconductor substrate 102 includes a semiconductor material that is monocrystalline. The semiconductor substrate 102 has an upper surface 120 in and/or on which devices (e.g., the BJT) are formed. The upper surface 120 may be a monocrystalline surface of the monocrystalline semiconductor material of the semiconductor substrate 102. The semiconductor substrate 102 may be or include a bulk semiconductor substrate, a semiconductor-on-insulator (SOI) substrate, or any other appropriate substrate. The semiconductor substrate 102 may also include a support (or handle) substrate and an epitaxial layer epitaxially grown on the support substrate. In some examples, the semiconductor substrate 102 is or includes a silicon substrate (which may be singulated from a bulk silicon wafer at the conclusion of semiconductor processing). In further examples, the semiconductor substrate 102 includes a silicon substrate with an epitaxial silicon layer grown thereon. In some examples, the semiconductor material is or includes silicon (Si), silicon germanium (SiGe), gallium arsenide (GaAs), gallium nitride (GaN), the like, or a combination thereof. In the illustrated example, the semiconductor material (e.g., silicon) of the semiconductor substrate 102 is p-type doped with a p-type dopant. In some examples, the semiconductor substrate 102 is p-type doped with a p-type dopant (e.g., boron (B)) with a concentration in a range from 1×10¹⁴ cm⁻³ to 1×10¹⁵ cm⁻³. Another dopant type and/or other doping concentrations may be implemented.

The first pedestal dielectric sub-layer 104 is formed over and on the upper surface 120 of the semiconductor substrate 102. In some examples, the first pedestal dielectric sub-layer 104 is or includes silicon oxide, which may be formed by in situ steam generation (ISSG) oxidation. The first pedestal dielectric sub-layer 104 may also be, for example, a pad oxide layer. Another dielectric material and/or formation or deposition technique may be implemented.

Isolation structures 132, 134 are formed in the semiconductor substrate 102. In the illustrated example, the isolation structures 132, 134 are shallow trench isolation structures (STIs) extending from the upper surface 120 of the semiconductor substrate 102 into the semiconductor substrate 102. As illustrated, the isolation structures 132, 134 are also through the first pedestal dielectric sub-layer 104 and are raised above the upper surface 120 of the semiconductor substrate 102. Each isolation structure 132, 134, in the illustrated example, has or is defined by planar sidewalls and a planar bottom surface. As illustrated, each isolation structure 132, 134 has a reentrant profile. The isolation structures 132, 134 may include, for example, a liner layer, such as including silicon oxide or silicon nitride, conformally along surfaces of a respective trench through the first pedestal dielectric sub-layer 104 and in the semiconductor substrate 102 and a fill isolation material, such as silicon oxide, over and on the liner layer.

To form the isolation structures 132, 134, trenches are formed through the first pedestal dielectric sub-layer 104 and in the semiconductor substrate 102. The trenches may be formed by patterning a hardmask layer, such as by using photolithography and an etching process (e.g., reactive ion etch (RIE)). The trenches are etched, such as by RIE, through the first pedestal dielectric sub-layer 104 and in the semiconductor substrate 102 using the patterned hardmask layer as a mask. The liner layer may then be conformally deposited in the trenches and over the patterned hardmask layer (e.g., by plasma enhanced chemical vapor deposition (PECVD) or formed on exposed surfaces of the trenches (e.g., by an oxidation process). The fill isolation material may be deposited over the liner layer, such as by high aspect ratio CVD (HAR-CVD), flowable CVD (FCVD), or the like. Excess fill isolation material and liner layer may be removed from over the hardmask layer by a planarization process, such as a chemical mechanical polish (CMP). The hardmask layer may then be removed by an etch selective to the hardmask layer, which may be a wet etch process. In other examples, the isolation structures 132, 134 may be field oxide structures, such as local oxidation of silicon (LOCOS) structures, at the upper surface 120 of the semiconductor substrate 102, which may be formed using a LOCOS process.

The isolation structures 132, 134 laterally surround and define an area (e.g., an active area) of the upper surface 120 of the semiconductor substrate 102 in and/or on which the BJT is to be formed. The isolation structures 132, 134 together laterally encircle or encompass the area of the upper surface 120 of the semiconductor substrate 102 in and/or on which the BJT is to be formed. The isolation structures 132, 134 may be a continuous isolation structure laterally encircling or encompassing, and hence, laterally defining, the area of the upper surface 120 of the semiconductor substrate 102 in and/or on which the BJT is to be formed. As indicated subsequently, an active portion (e.g., a base layer) of the BJT extends laterally beyond the area of the upper surface 120 of the semiconductor substrate 102 in and/or on which the BJT is formed and over the isolation structure 132.

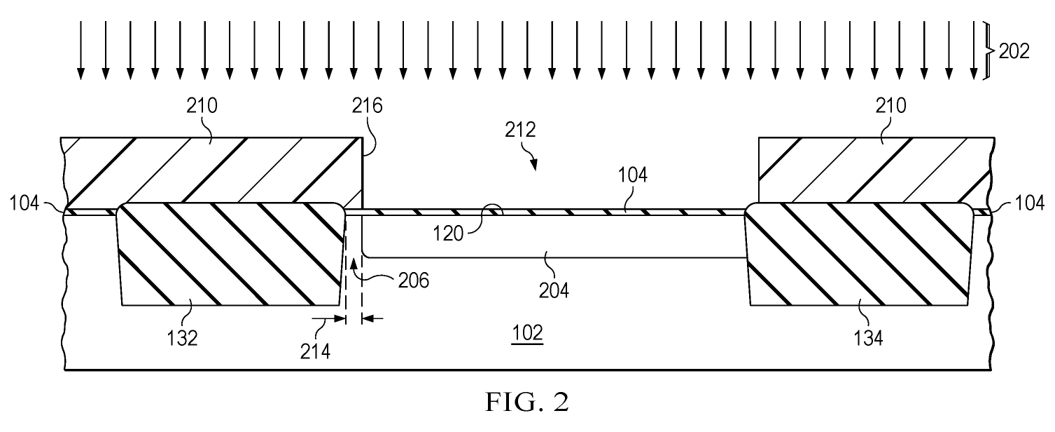

Referring to FIG. 2, an implantation 202 of an n-type dopant is performed to form a first doped region 204 in the semiconductor substrate 102. The implantation 202 implants the n-type dopant into the first doped region 204 in the semiconductor substrate 102 (e.g., in the area surrounded by the isolation structures 132, 134). The implantation 202 is performed using a mask (e.g., a blocking material) over the semiconductor substrate 102. In the illustrated example, the mask includes a photoresist 210. The photoresist 210 is patterned using photolithography. The photoresist 210 has an opening 212 corresponding to the first doped region 204. The photoresist 210 extends laterally an overhang distance 214 from a sidewall (e.g., planar sidewall) of the isolation structure 132 to a sidewall 216 of the opening 212. The photoresist 210 therefore extends laterally over the area that is laterally surrounded by the isolation structures 132, 134. Using the photoresist 210 as a mask, the n-type dopant is implanted 202 into the semiconductor substrate 102. The implantation 202 is performed in a direction at an angle substantially normal (e.g., within 10º of normal, and more particularly, within 7º of normal) to the upper surface 120 of the semiconductor substrate 102. The implantation 202 implants the n-type dopant through the opening 212 through the photoresist 210 and into the first doped region 204.The photoresist 210 blocks the n-type dopant from being implanted in a non-implanted region 206 in the area in the semiconductor substrate 102 that is covered by the photoresist 210. The non-implanted region 206 is in the semiconductor substrate 102 at, and extends laterally from, the sidewall (e.g., planar sidewall) of the isolation structure 132 from which the photoresist 210 laterally extends. The first doped region 204 laterally adjoins the non-implanted region 206.

In some examples, a dose of the implantation 202 of the n-type dopant is equal to or greater than a dose of the n-type dopant that amorphizes the semiconductor substrate 102 where the n-type dopant is implanted. For example, assuming the n-type dopant includes phosphorus, the dose of implanting phosphorous may be equal to or greater than 5×10¹⁴ cm⁻² (e.g., equal to or greater than 1×10¹⁵ cm⁻²) to amorphize silicon. Further, carbon may also be implanted, such as to reduce diffusion of phosphorus in silicon, and the dose of implanting carbon may be equal to or greater than 3×10¹⁵ cm⁻² to amorphize silicon. In some examples, arsenic may be implanted instead of or in addition to implanting phosphorus. Assuming the n-type dopant includes arsenic, the dose of implanting arsenic may be equal to or greater than 1×10¹⁴ cm⁻² to amorphize silicon. Hence, in some examples, the implantation 202 causes the first doped region 204 to be amorphized, and further, due to the n-type dopant of the implantation 202 being blocked by the photoresist 210, the non-implanted region 206 may remain crystalline (e.g., monocrystalline semiconductor material of the semiconductor substrate 102).

Generally, in examples in which the implantation 202 causes the first doped region 204 to be amorphized, the overhang distance 214 is sufficient, in consideration with any non-normal angle of the implantation 202, to cause the non-implanted region 206 to remain at and proximate to the sidewall (e.g., planar sidewall) of the isolation structure 132. As described subsequently, during a recrystallization process (e.g., an anneal), the non-implanted region 206 may be a crystalline seed for recrystallization of the amorphized first doped region 204, which may permit avoiding or reducing crystalline defect formation (e.g., formation of stacking faults and/or twin defects) originating from the sidewall of the isolation structure 132 during the recrystallization. In some examples, the overhang distance 214 is in a range from 15 nm to 65 nm. Other overhang distances may be implemented in other examples.

For illustration purposes, the photoresist 210 does not laterally extend from a sidewall of the isolation structure 134 over the area that is laterally surrounded by the isolation structures 132, 134. Hence, in the illustrated example, the first doped region 204 that is amorphized adjoins the sidewall of the isolation structure 134. In other examples, the photoresist 210 may laterally extend from the sidewall of the isolation structure 134 over the area that is laterally surrounded by the isolation structures 132, 134, like described above with respect to the isolation structure 132.

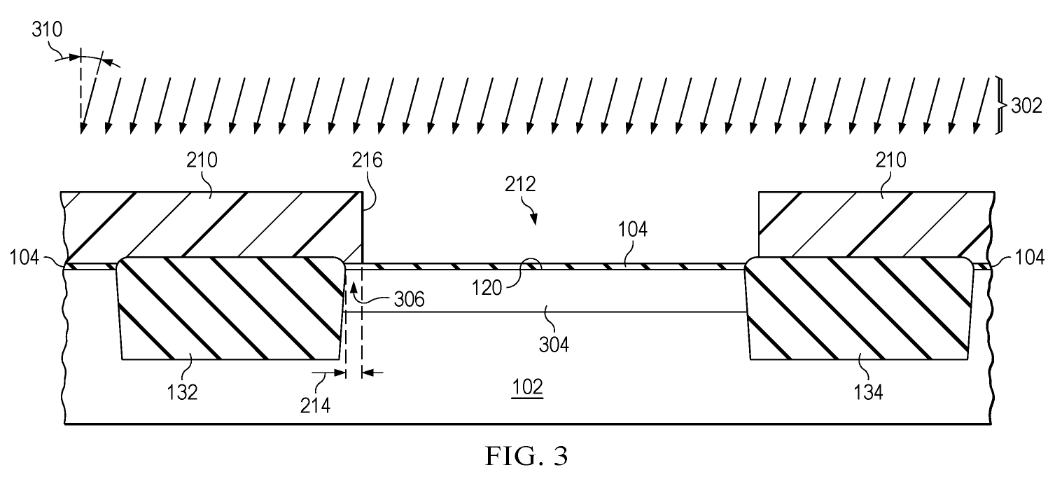

Referring to FIG. 3, optionally, an implantation 302 of an n-type dopant is performed. The implantation 302 forms a first doped region 304 where the first doped region 204 of FIG. 2 was formed and forms a second doped region 306 where the non-implanted region 206 was in the semiconductor substrate 102. The implantation 302 implants the n-type dopant into the first doped region 304 and the second doped region 306 in the semiconductor substrate 102 (e.g., in the area surrounded by the isolation structures 132, 134). The n-type dopant of the implantation 302 of FIG. 3 may be or include a same or different dopant type, and further, a same or different dopant species, of the n-type dopant of the implantation 202 of FIG. 2. Using the photoresist 210 formed in FIG. 2 as a mask, the n-type dopant is implanted 302 into the semiconductor substrate 102. The implantation 302 is performed in a direction at an angle 310 with respect to normal to the upper surface 120 of the semiconductor substrate 102. The angle 310 may be in a range from 15º to 45º. The implantation 302 implants the n-type dopant through the opening 212 through the photoresist 210 and into the first doped region 304. The implantation 302 further implants the n-type dopant in the second doped region 306 that is covered by the photoresist 210 near the opening 212 and that was not implanted by the implantation 202 of FIG. 2 (the non-implanted region 206). The second doped region 306 is in the semiconductor substrate 102 at, and extends laterally from, the sidewall (e.g., planar sidewall) of the isolation structure 132 from which the photoresist 210 laterally extends. The first doped region 304 laterally adjoins the second doped region 306.

In some examples, a dose of the implantation 302 of the n-type dopant is less than a dose of the n-type dopant that amorphizes the semiconductor substrate 102 where the n-type dopant is implanted. For example, assuming the n-type dopant includes phosphorus, the dose of implanting phosphorous may be less than 5×10¹⁴ cm⁻² (e.g., equal to or less than 5×10¹³ cm⁻²) so that silicon is not amorphized by the implantation. Further, carbon may also be implanted, such as to reduce diffusion of phosphorus in silicon, and the dose of implanting carbon may be less than 3×10¹⁵ cm⁻² so that silicon is not amorphized by the implantation. In some examples, arsenic may be implanted instead of or in addition to implanting phosphorus. Assuming the n-type dopant includes arsenic, the dose of implanting arsenic may be less than 1×10¹⁴ cm⁻² so that silicon is not amorphized by the implantation. Hence, in some examples, the implantation 302 does not cause the second doped region 306 to be amorphized. Hence, due to the blocking by the photoresist 210 during the implantation 202 of FIG. 2 and the dose of the implantation 302 of FIG. 3 being less than a dose to amorphize the semiconductor substrate 102, the second doped region 306 may remain crystalline (e.g., monocrystalline semiconductor material of the semiconductor substrate 102). Following the implantation 302 of FIG. 3 or the implantation 202 of FIG. 2 if the implantation 302 of FIG. 3 is omitted, the mask (e.g., photoresist 210) is removed, such as by an ashing and/or a wet process.

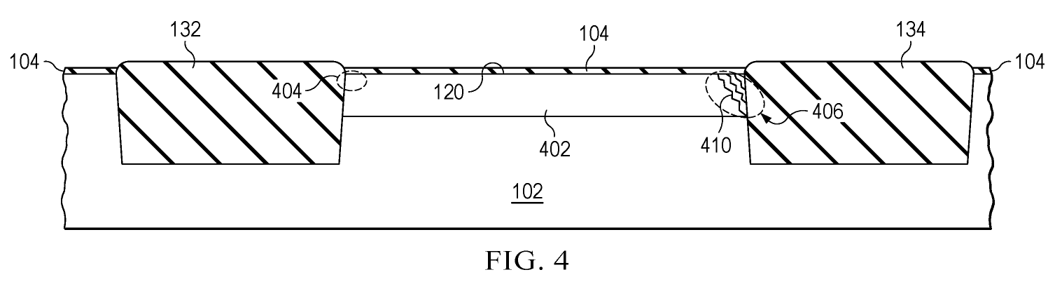

Referring to FIG. 4, following the implantation 202 of FIG. 2 and/or the implantation 302 of FIG. 3 (if implemented), an anneal process is performed on the semiconductor substrate 102, which results in an n-type doped sub-collector region 402 in the semiconductor substrate 102. The anneal process activates the n-type dopants implanted by the implantation 202 of FIG. 2 and, if implemented, the implantation 302 of FIG. 3 for the n-type doped sub-collector region 402 and recrystallizes the semiconductor material of the semiconductor substrate 102 that was amorphized by the implantation 202 of the n-type dopant. The n-type dopants implanted by the implantations 202, 302 may also diffuse during the anneal process to form the n-type doped sub-collector region 402 laterally extending from the isolation structure 132 to the isolation structure 134. In some examples, the anneal process is a rapid thermal anneal (RTA). The RTA may reach a peak temperature of equal to or greater than 500 ºC, such as in a range from 500 ºC to 1,200 ºC (e.g., 1,000 ºC), and may have a duration of equal to or less than 2 minutes. For example, an RTA may reach a peak temperature of 1,050 ºC with a ramping of temperature at a rate of 35 ºC per second over a duration of 30 seconds. The RTA may be performed in an ambient environment that includes oxygen (O₂) gas, a forming gas, the like, or a combination thereof. In other examples, other anneal processes may be implemented, such as a furnace anneal.

Following the anneal process, the n-type doped sub-collector region 402 is crystallized generally to the crystalline orientation of the semiconductor substrate 102. Crystalline defects, such as stacking faults and/or twin defects, above a detectable threshold are not generated (e.g., no stacking faults and/or twin defects are generated) in the n-type doped sub-collector region 402 originating at the sidewall (e.g., planar sidewall) of the isolation structure 132 when the n-type doped sub-collector region 402 is recrystallized. For example, using a transmission electron microscope (TEM) to detect crystalline defects (e.g., stacking faults and/or twin defects), no perceptible phase contrast may be present in the TEM image in the semiconductor material of the semiconductor substrate 102 at the sidewall of the isolation structure 132 (in the n-type doped sub-collector region 402) relative to a bulk area of the semiconductor material of the semiconductor substrate 102. The non-implanted region 206 or second doped region 306, which was not amorphized by the implantations 202, 302, provides a crystalline seed for recrystallization of the amorphized first doped region 204, 304. This crystalline seed is between the amorphous surface (e.g., the sidewall) of the isolation structure 132 such that no amorphous surface extending into the semiconductor material of the semiconductor substrate 102 interfaces with the amorphized first doped region 204, 304 that is being recrystallized. The amorphized first doped region 204, 304 not interfacing with such an amorphous surface may permit reducing or avoiding generating crystalline defects (e.g., stacking faults and/or twin defects) above a detectable threshold originating at the sidewall of the isolation structure 132 when the n-type doped sub-collector region 402 is recrystallized. For example, stacking faults and/or twin defects above a detectable threshold are not in a corner region 404 in the semiconductor substrate 102 at the sidewall of the isolation structure 132 and the upper surface 120 of the semiconductor substrate 102.

As previously indicated, the amorphized first doped region 204, 304 may adjoin a sidewall of the isolation structure 134. During the anneal process, the sidewall of the isolation structure 134 may be an amorphous surface that interfaces with the amorphized first doped region 204, 304 that is being recrystallized. Hence, stacking faults 410 may be generated originating from the sidewall of the isolation structure 134. As illustrated, stacking faults 410 are in a corner region 406 in the semiconductor substrate 102 at the isolation structure 134 and the upper surface 120 of the semiconductor substrate 102. In other examples where the photoresist 210 laterally extends from the sidewall of the isolation structure 134, a corner region similar to the corner region 404 (e.g., with reduced or no stacking faults) may be formed in the semiconductor substrate 102 at the isolation structure 134 and the upper surface 120 of the semiconductor substrate 102.

The n-type doped sub-collector region 402 extends from the upper surface 120 of the semiconductor substrate 102 into a depth in the semiconductor substrate 102. A concentration of the n-type doped sub-collector region 402 is greater than a concentration of the p-type dopant of the semiconductor substrate 102. The concentration of the n-type doped sub-collector region 402 may be a high concentration, such as equal to or greater than 1×10¹⁸ cm⁻³ (e.g., equal to or greater than 3×10²⁰ cm⁻³). In some examples, the n-type doped sub-collector region 402 is doped with an n-type dopant with a concentration in a range from 1×10¹⁸ cm⁻³ to 1×10²⁰ cm⁻³. Another doping concentration may be implemented.

Although the semiconductor substrate 102 and n-type doped sub-collector region 402 are described herein as being doped with a certain dopant conductivity type, such components may be doped with an opposite conductivity type (e.g., being n-type doped instead of p-type doped, and vice versa) in other examples. Similarly, subsequently described components that are described as being doped with a certain dopant conductivity type may also be doped with an opposite conductivity type in other examples.

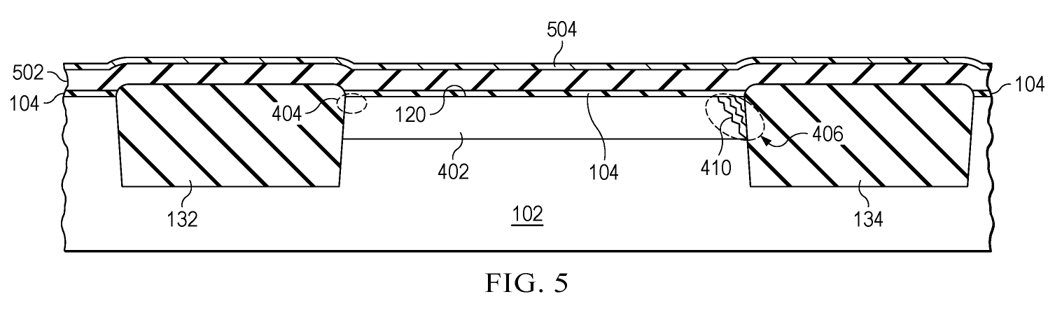

Referring to FIG. 5, a second pedestal dielectric sub-layer 502 is formed over and on the first pedestal dielectric sub-layer 104, and a hardmask layer 504 is formed over and on the second pedestal dielectric sub-layer 502. The second pedestal dielectric sub-layer 502 may also be formed over and on the isolation structures 132, 134. In some examples, the second pedestal dielectric sub-layer 502 is or includes silicon oxide (e.g., a tetraethyl orthosilicate (TEOS) oxide), which may be deposited by CVD, such as PECVD. Another dielectric material and/or formation or deposition technique may be implemented. In some examples, the hardmask layer 504 is or includes silicon nitride, which may be deposited by CVD. Any dielectric material that may be selectively etched relative to the second pedestal dielectric sub-layer 502 and/or the first pedestal dielectric sub-layer 104 may be implemented for the hardmask layer 504, and any appropriate deposition process may be implemented to form the hardmask layer 504.

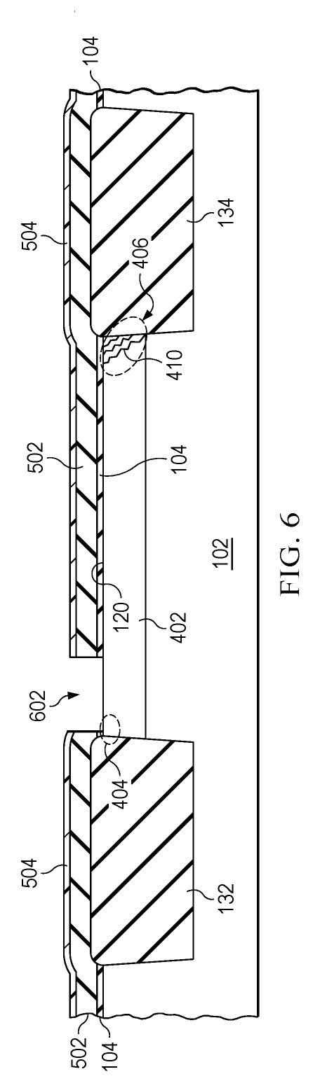

Referring to FIG. 6, the hardmask layer 504, the second pedestal dielectric sub-layer 502, and the first pedestal dielectric sub-layer 104 are etched to form a collector opening 602 through the hardmask layer 504, the second pedestal dielectric sub-layer 502, and the first pedestal dielectric sub-layer 104. The upper surface 120 of the semiconductor substrate 102 is exposed through the collector opening 602. The collector opening 602 generally extends from proximate to (or some lateral distance from) the isolation structure 132 laterally away from the isolation structure 132 in the area surrounded by the isolation structures 132, 134. The hardmask layer 504, the second pedestal dielectric sub-layer 502, and the first pedestal dielectric sub-layer 104 may be etched using appropriate photolithography and etching processes. For example, an anisotropic etch, such as an RIE, may be implemented.

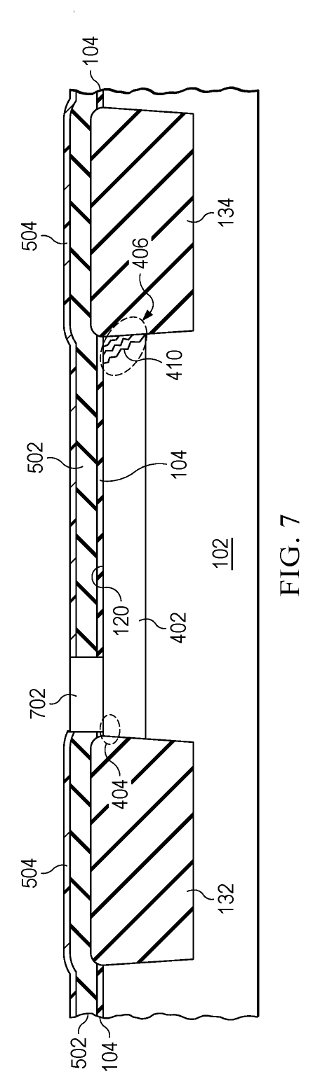

Referring to FIG. 7, a collector layer 702 is formed over (e.g., on) the upper surface 120 of the semiconductor substrate 102 and in the collector opening 602. In some examples, the collector layer 702 is or includes a semiconductor layer doped with an n-type dopant (e.g., a same dopant type as the n-type doped sub-collector region 402). In some examples, the collector layer 702 is or includes silicon. In some examples, the collector layer 702 is doped with an n-type dopant with a concentration in a range from 1×10¹⁹ cm⁻³ to 1×10²¹ cm⁻³. The collector layer 702 may be epitaxially grown on the upper surface 120 of the semiconductor substrate 102. The collector layer 702 may be epitaxially grown by a selective epitaxial growth process in some examples. The epitaxial growth of the collector layer 702 on the upper surface 120 of the semiconductor substrate 102 may result in the collector layer 702 being monocrystalline. Further, the collector layer 702 may be in situ doped during the epitaxial growth process (e.g., the selective epitaxial growth process). The epitaxial growth process may be a CVD process, such as a low pressure CVD (LPCVD), reduced pressure CVD (RPCVD), metal organic CVD (MOCVD), or the like. Other materials, dopant type, dopant concentration, and/or deposition process may be implemented.

Subsequent to the formation of the collector layer 702, processing may proceed as described in U.S. Patent Application Serial No. 18/520,527, filed on Nov. 27, 2023, entitled “SEMICONDUCTOR PROCESSING INTEGRATION FOR BIPOLAR JUNCTION TRANSISTOR (BJT)”, which is incorporated herein by reference in its entirety. Such processing may continue through formation of the BJT. Such processing includes forming a base layer over (e.g., on) the collector layer 702 and forming an emitter layer over (e.g., on) the base layer.

FIG. 8 is a cross-sectional view of a semiconductor device 800 according to some examples. The semiconductor device 800 is or includes a BJT. The BJT includes the collector layer 702, a base layer 802 (e.g., monocrystalline base layer 802a and polycrystalline base layer 802b), and an emitter layer 804 (e.g., monocrystalline emitter layer 804a and polycrystalline emitter layer 804b). As illustrated, the BJT does not include a raised base layer, and in other examples, the BJT may include a raised base layer on the base layer, as described in U.S. Patent Application Serial No. 18/520,527.

In some examples, the base layer 802 is or includes a semiconductor layer doped with a p-type dopant (e.g., an opposite dopant type as the collector layer 702). In some examples, the base layer 802 is or includes silicon germanium. In some examples, the base layer 802 is doped with a p-type dopant with a concentration in a range from 1×10¹⁷ cm⁻³ to 1×10²¹ cm⁻³. The base layer 802 may also be doped with carbon (C) to prevent or reduce diffusion of the p-type dopant. In some examples, the emitter layer 804 is or includes a semiconductor layer doped with an n-type dopant (e.g., an opposite dopant type from the base layer 802). In some examples, the emitter layer 804 is or includes silicon. In some examples, the emitter layer 804 is doped with an n-type dopant with a concentration in a range from 1×10¹⁹ cm⁻³ to 1×10²¹ cm⁻³. Other doping concentrations of the base layer 802 and/or emitter layer 804 may be implemented. As described, with the collector layer 702 and the emitter layer 804 being doped with n-type dopants, and the base layer 802 being doped with a p-type dopant, the BJT in the described example is an NPN BJT. In other examples, the BJT may be a PNP BJT.

The collector layer 702 is over and on the upper surface 120 of the semiconductor substrate 102 and is through an opening in a pedestal dielectric stack (e.g., the second pedestal dielectric sub-layer 502 and first pedestal dielectric sub-layer 104), which is also over the upper surface 120 (e.g., in the area laterally surrounded by the isolation structures 132, 134) of the semiconductor substrate 102. The collector layer 702 is on the n-type doped sub-collector region 402 in the semiconductor substrate 102. The base layer 802 (e.g., the monocrystalline base layer 802a) is over and on the collector layer 702, and the base layer 802 (e.g., the polycrystalline base layer 802b) is over and on an upper surface of the pedestal dielectric stack (e.g., the second pedestal dielectric sub-layer 502).

The pedestal dielectric stack (e.g., the pedestal dielectric sub-layers 104, 502) underlies the base layer 802. The pedestal dielectric stack extends laterally from the base layer 802 (e.g., the polycrystalline base layer 802b). For example, the pedestal dielectric stack (e.g., the pedestal dielectric sub-layers 104, 502) extends over and on the isolation structure 132 laterally away from a corresponding sidewall of the polycrystalline base layer 802b to a sidewall 806 of the pedestal dielectric stack over the isolation structure 132. Additionally, the pedestal dielectric stack extends over and on the upper surface 120 of the semiconductor substrate 102 over the n-type doped sub-collector region 402 and laterally away from a corresponding sidewall of the polycrystalline base layer 802b to a sidewall 808 of the pedestal dielectric stack proximate an n-type collector contact region 810.

The n-type collector contact region 810 is in the n-type doped sub-collector region 402 in the semiconductor substrate 102. The n-type collector contact region 810 is laterally between the pedestal dielectric stack and the isolation structure 134. A concentration of the n-type dopant of the n-type collector contact region 810 is greater than the concentration of the n-type dopant of the n-type doped sub-collector region 402. In some examples, the n-type collector contact region 810 is doped with an n-type dopant with a concentration in a range from 1×10²⁰ cm⁻³ to 1×10²¹ cm⁻³. Other doping concentrations may be implemented.

The emitter layer 804 (e.g., the monocrystalline emitter layer 804a) is over and on the base layer 802 (e.g., the monocrystalline base layer 802a) and is through an opening defined by a spacer structure, and the emitter layer 804 (e.g., the polycrystalline emitter layer 804b) is over and on the spacer structure. The spacer structure includes a first dielectric spacer layer 812 and a second dielectric spacer layer 814. In some examples, the second dielectric spacer layer 814 is a dielectric material different from the dielectric material of the first dielectric spacer layer 812. In some examples, the first dielectric spacer layer 812 is silicon oxide (e.g., a TEOS oxide), and the second dielectric spacer layer 814 is silicon nitride. Other dielectric materials may be used in other examples. Other spacer structures may be implemented.

Metal-semiconductor compound 822 is on the emitter layer 804 (e.g., the polycrystalline emitter layer 804b and/or monocrystalline emitter layer 804a). Metal-semiconductor compound 824 is on the base layer 802 (e.g., the polycrystalline base layer 802b). Metal-semiconductor compound 826 is on the upper surface 120 of the semiconductor substrate 102 on the n-type collector contact region 810. The metal-semiconductor compound 822, 824, 826 may be a silicide (e.g., NiSix, TiSix, CoSix, PtSix), a germanicide, or the like.

A dielectric layer 832 is formed over the semiconductor substrate 102 (e.g., over the BJT), and metal contacts 842, 844, 846 are formed through the dielectric layer 832. The dielectric layer 832 may include one or more dielectric sub-layers. For example, the dielectric layer 832 may include a conformal first dielectric sub-layer over the semiconductor substrate 102 and a second dielectric sub-layer over the first dielectric sub-layer. The conformal first dielectric sub-layer may be a stressor layer, an etch stop layer, or the like, which may be or include silicon nitride, silicon oxynitride, the like, or a combination thereof. The second dielectric sub-layer may be or include silicon oxide, silicon nitride, or the like. The dielectric layer 832 may be or include a pre-metal dielectric (PMD), an inter-layer dielectric (ILD), or the like. The metal contacts 842, 844, 846 extend through the dielectric layer 832 and contact respective metal-semiconductor compound 822, 824, 826. The metal contacts 842, 844, 846 may each include one or more barrier and/or adhesion layers (e.g., titanium nitride (TiN), tantalum nitride (TaN), the like, or a combination thereof) conformally in a respective opening through the dielectric layer 832, and a fill metal (e.g., tungsten (W), copper (Cu), aluminum (Al), the like, or a combination thereof) over and/or on the barrier and/or adhesion layer(s).

In some examples, the BJT may be a heterojunction BJT. As indicated previously, in some examples, the collector layer 702 and the emitter layer 804 may be silicon, and the base layer 802 may include silicon germanium. Hence, in some examples, the base layer 802 may include a semiconductor material dissimilar from respective semiconductor materials of the collector layer 702 and emitter layer 804. The dissimilar semiconductor materials may form one or more heterojunctions in the BJT, and the BJT may therefore be a heterojunction BJT.

As stated previously, the reduction of crystalline defects (e.g., stacking faults and/or twin defects) at, e.g., the corner region 404 may reduce leakage of the BJT in FIG. 8. Reducing crystalline defects at the corner region 404 may permit the collector layer 702 to be formed in close proximity to the isolation structure 132, which may reduce a base-to-collector capacitance. Reduced leakage and reduced base-to-collector capacitance may result in improved electrical performance of the BJT.

Although various examples have been described in detail, it should be understood that various changes, substitutions, and alterations can be made therein without departing from the scope defined by the appended claims.

What is claimed is:

1. A method, comprising:
forming an isolation structure in a semiconductor substrate, the isolation structure extending from an upper surface of the semiconductor substrate into the semiconductor substrate, wherein the isolation structure laterally surrounds at least in part an area of a bipolar junction transistor (BJT) in the semiconductor substrate;
implanting a first dopant in a first region of the area, wherein a second region of the area proximate a sidewall of the isolation structure is covered with a material blocking the first dopant; and
forming a collector layer on the area.

2. The method of claim 1, wherein the first dopant is implanted with an angle substantially normal to the upper surface of the semiconductor substrate.

3. The method of claim 1, wherein the first dopant is not implanted in the second region of the area at the sidewall of the isolation structure.

4. The method of claim 1, wherein implanting the first dopant amorphizes the semiconductor substrate where the first dopant is implanted.

5. The method of claim 1, wherein the first dopant is an n-type dopant, and a dose of the first dopant during implanting the first dopant is equal to or exceeds 5 × 10¹⁴ cm⁻².

6. The method of claim 1, further comprising implanting a second dopant in the area, wherein the second dopant is a same dopant type as the first dopant.

7. The method of claim 6, wherein implanting the second dopant is after implanting the first dopant.

8. The method of claim 6, wherein the second dopant is implanted with an angle in a range from 15º to 45º from normal to the upper surface of the semiconductor substrate.

9. The method of claim 6, wherein the second dopant is implanted in the second region of the area at the sidewall of the isolation structure.

10. The method of claim 6, wherein implanting the second dopant does not amorphize the semiconductor substrate where the second dopant is implanted.

11. The method of claim 6, wherein the second dopant is an n-type dopant, and a dose of the second dopant during implanting the second dopant is less than 1 × 10¹⁴ cm⁻².

12. The method of claim 1, further comprising performing an anneal after implanting the first dopant and before forming the collector layer.

13. A method, comprising:
forming an isolation structure in a semiconductor substrate, the isolation structure extending from an upper surface of the semiconductor substrate into the semiconductor substrate, wherein the isolation structure laterally surrounds at least in part an area of a bipolar junction transistor (BJT) in the semiconductor substrate;
forming a mask over the semiconductor substrate, the mask having an opening exposing a portion of the area, the mask extending laterally from over the isolation structure to a mask sidewall of the opening over the area;
implanting, through the opening, a first dopant in the portion of the area; and
forming a collector layer on the area.

14. The method of claim 13, wherein the first dopant is not implanted in a portion of the semiconductor substrate that is at an isolation sidewall of the isolation structure in the area and underlies the mask.

15. The method of claim 13, wherein implanting the first dopant amorphizes the semiconductor substrate where the first dopant is implanted.

16. The method of claim 13, further comprising implanting, through the opening, a second dopant in the area, wherein the second dopant is a same dopant type as the first dopant.

17. The method of claim 16, wherein the second dopant is implanted in the area underlying the mask that extends laterally from over the isolation structure to the mask sidewall of the opening.

18. The method of claim 16, wherein the second dopant is implanted with an angle in a range from 15º to 45º from normal to the upper surface of the semiconductor substrate.

19. The method of claim 16, wherein implanting the second dopant does not amorphize the semiconductor substrate where the second dopant is implanted.

20. The method of claim 13, further comprising performing an anneal after implanting the first dopant and before forming the collector layer.
